(19) United States
(12) Patent Application Publication
(10) Pub. No.: US 2026/0206138 A1
(43) Pub. Date: Jul. 16, 2026

(54) THROUGH-CONDUCTOR BUILT-IN SUBSTRATE

(71) Applicant: Murata Manufacturing Co., Ltd., Nagaokakyo-shi (JP)

(72) Inventor: Hidehiko SASAKI, Nagaokakyo-shi (JP)

(21) Appl. No.: 19/560,237

(22) Filed: Mar. 9, 2026

Related U.S. Application Data
(63) Continuation of application No. PCT/JP2024/013193, filed on Mar. 29, 2024.

(30) Foreign Application Priority Data
Sep. 12, 2023 (JP) 2023-147644

(51) Int. Cl. H05K 1/11

(52) U.S. Cl. CPC H05K 1/115

(57) ABSTRACT

A through-conductor built-in substrate includes a base plate having opposing first and second main surfaces and a plurality of through holes extending therebetween. Through conductors are inserted in the through holes and connected to a metal layer extending in a surface direction of the first main surface. The through holes include first and second through holes with corresponding first and second through conductors inserted therein. A first reference line passes through centers of the first and second through holes. The first through conductor contacts or is proximate to an intersection of the inner peripheral wall of the first through hole and the first reference line on a far side from the second through hole. The second through conductor contacts or is proximate to an intersection of the inner peripheral wall of the second through hole and the first reference line on a far side from the first through hole.

### CROSS REFERENCE TO RELATED APPLICATIONS

This application is a continuation of International Application No. PCT/JP2024/013193, filed March 29, 2024, which claims priority to Japanese Patent Application No. 2023-147644, filed September 12, 2023, the contents of each of which are hereby incorporated by reference in their entireties.

### TECHNICAL FIELD

The present disclosure relates to a through-conductor built-in substrate.

### BACKGROUND

For example, Japanese Unexamined Patent Application Publication No. 2020-047643 (the ”’643 Publication”) discloses a glass substrate that includes a through conductor and a resin body, the through conductor being formed in a through hole extending through the glass substrate in a thickness direction, the resin body being disposed between the through conductor and the through hole and surrounding the through conductor.

In a structure such as that in the ’643 Publication, a wiring layer may be provided on the glass substrate or a heat-dissipating layer made of a metal may be provided for heat dissipation of a heat spreader. The wiring layer or the heat-dissipating layer is connected to the through conductor.

The wiring layer or a heat-dissipating plate thermally expands when the temperature of a use environment rises. In particular, when the temperature rises due to the use of, for example, a semiconductor that is connected to the glass substrate, the wiring layer or the heat-dissipating plate may be excessively heated to a higher temperature than normal temperature.

At this time, since the thermal expansion coefficient of the wiring layer or the heat-dissipating plate is higher than the thermal expansion coefficient of the glass substrate, the wiring layer or the heat-dissipating plate expands in a planar direction with respect to the glass substrate due to the heating. Since the through conductor is connected to the wiring layer or the heat-dissipating layer, stress is applied to the through conductor so as to move the through conductor in the planar direction of the glass substrate.

In the technology described in the ’643 Publication, what surrounds the through conductor is the resin body. Since the resin is a material that is softer than the through conductor, when the stress that moves the through conductor in the planar direction of the glass substrate is applied to the through conductor, the resin body cannot prevent the movement of the through conductor and thus the through conductor deforms the resin body and moves in the planar direction of the glass substrate due to the stress.

In addition, problems such as warping of the glass substrate due to the movement of the through conductor may occur.

### SUMMARY OF THE INVENTION

The present disclosure has been made for solving the above-described problems, and it is an object of the present disclosure to provide a through-conductor built-in substrate in which movement, caused by thermal stress, of a through conductor inserted in a through hole is prevented.

A through-conductor built-in substrate of the present disclosure includes: a base plate that includes a first main surface, a second main surface, and a plurality of through holes, the second main surface being opposite to the first main surface, the plurality of through holes extending along the second main surface from the first main surface; through conductors that are inserted in the through holes; and a metal layer that extends in a surface direction that is same as a surface direction of the first main surface, the metal layer being connected to the through conductors, wherein the through holes include a first through hole and a second through hole, which are different through holes, wherein the through conductors include a first through conductor and a second through conductor, the first through conductor being inserted in the first through hole, the second through conductor being inserted in the second through hole, wherein the first through conductor and the second through conductor are each connected to the metal layer, and wherein, when a straight line that passes through a center of the first through hole and a center of the second through hole is a first reference line, the first through conductor contacts or is near, of intersections of an inner peripheral wall of the first through hole and the first reference line, a first intersection, which is an intersection on a far side from the second through hole, and the second through conductor contacts or is near, of intersections of an inner peripheral wall of the second through hole and the first reference line, a second intersection, which is an intersection on a far side from the first through hole.

A through-conductor built-in substrate of a different aspect of the present disclosure includes: a base plate that includes a first main surface, a second main surface, and a plurality of through holes, the second main surface being opposite to the first main surface, the plurality of through holes extending along the second main surface from the first main surface; through conductors that are inserted in the through holes; and a metal layer that extends in a surface direction that is same as a surface direction of the first main surface, the metal layer being connected to the through conductors, wherein the through holes include a third through hole, a fourth through hole, and a fifth through hole, which are different through holes, wherein the through conductors include a third through conductor, a fourth through conductor, and a fifth through conductor, the third through conductor being inserted in the third through hole, the fourth through conductor being inserted in the fourth through hole, the fifth through conductor being inserted in the fifth through hole, wherein the third through conductor, the fourth through conductor, and the fifth through conductor are each connected to the metal layer, and wherein, when a straight line that passes through a center of the third through hole and a center of the fourth through hole is a third reference line, a straight line that passes through the center of the fourth through hole and a center of the fifth through hole is a fourth reference line, and a straight line that passes through the center of the fifth through hole and the center of the third through hole is a fifth reference line, the third through conductor contacts or is near a portion between, of intersections of an inner peripheral wall of the third through hole and the third reference line, a third intersection and, of intersections of the inner peripheral wall of the third through hole and the fifth reference line, a fourth intersection, the third intersection being an intersection on a far side from the fourth through hole, the fourth intersection being an intersection on a far side from the fifth through hole, the fourth through conductor contacts or is near a portion between, of intersections of an inner peripheral wall of the fourth through hole and the fourth reference line, a fifth intersection and, of intersections of the inner peripheral wall of the fourth through hole and the third reference line, a sixth intersection, the fifth intersection being an intersection on a far side from the fifth through hole, the sixth intersection being an intersection on a far side from the third through hole, and the fifth through conductor contacts or is near a portion between, of intersections of an inner peripheral wall of the fifth through hole and the fifth reference line, a seventh intersection and, of intersections of the inner peripheral wall of the fifth through hole and the fourth reference line, an eighth intersection, the seventh intersection being an intersection on a far side from the third through hole, the eighth intersection being an intersection on a far side from the fourth through hole.

According to the present disclosure, a through-conductor built-in substrate is provided in which movement, caused by thermal stress, of a through conductor inserted in a through hole is prevented.

### BRIEF DESCRIPTION OF DRAWINGS

In the descriptions that follow, like parts are marked throughout the specification and drawings with the same numerals, respectively. The drawings are not necessarily drawn to scale and certain drawings may be illustrated in exaggerated or generalized form in the interest of clarity and conciseness. The disclosure itself, however, as well as a mode of use, further features and advances thereof, will be understood by reference to the following detailed description of illustrative implementations of the disclosure when read in conjunction with reference to the accompanying drawings, wherein:

FIG. 1 is a top view of a through-conductor built-in substrate according to an aspect of the present disclosure when viewed from a first main surface side of a base plate;

FIG. 2 is a top view of a region S portion of the through-conductor built-in substrate shown in FIG. 1 in accordance with aspects of the present disclosure;

FIG. 3 is a cross-sectional view taken along line A-A of the through-conductor built-in substrate shown in FIG. 1, and shows a structure including a metal layer on the first main surface side and a metal layer on a second main surface side of the base plate in accordance with aspects of the present disclosure;

FIG. 4 is an explanatory view illustrating a positional relationship when a through conductor and an intersection are near each other in accordance with aspects of the present disclosure;

FIG. 5 is a top view showing three through holes and three through conductors that are focused upon in accordance with aspects of the present disclosure;

FIG. 6 is an explanatory view illustrating a positional relationship when a through conductor is near a portion between an intersection and an intersection in accordance with aspects of the present disclosure;

FIG. 7 is a top view illustrating a positional relationship between two through holes and two through conductors that are focused upon, and a metal layer in accordance with aspects of the present disclosure;

FIG. 8 is a top view illustrating a positional relationship between two through holes and two through conductors that are focused upon, and a metal layer in accordance with aspects of the present disclosure;

FIG. 9 is a top view showing a positional relationship between three through holes and three through conductors that are focused upon, and a metal layer in accordance with aspects of the present disclosure;

FIG. 10 is a cross-sectional view schematically showing a form in which a through conductor is in line-contact with an inner peripheral wall of a through hole in which the through conductor is inserted in accordance with aspects of the present disclosure;

FIG. 11 is a cross-sectional view schematically showing a form in which the length of a through conductor is less than the length of a through hole in accordance with aspects of the present disclosure;

FIG. 12 is a cross-sectional view schematically showing a form in which a side surface of a through conductor has an uneven portion in accordance with aspects of the present disclosure; and

FIG. 13 is a cross-sectional view schematically showing a form in which an inner peripheral wall of a through hole has an uneven portion in accordance with aspects of the present disclosure.

### DETAILED DESCRIPTION

Hereinbelow, aspects of the present disclosure will be described. In a following description of the drawings, the same or similar components will be represented with use of the same or similar reference characters. The drawings are exemplary, sizes or shapes of portions are schematic, and technical scope of the present disclosure should not be understood with limitation to the aspects.

A through-conductor built-in substrate of the present disclosure is described below.

However, the present disclosure is not limited to the structures below, and is applicable by making changes as appropriate within a scope that does not change the spirit of the present disclosure. It should be noted that combinations of two or more individual preferred structures that are described below also art part of the present disclosure.

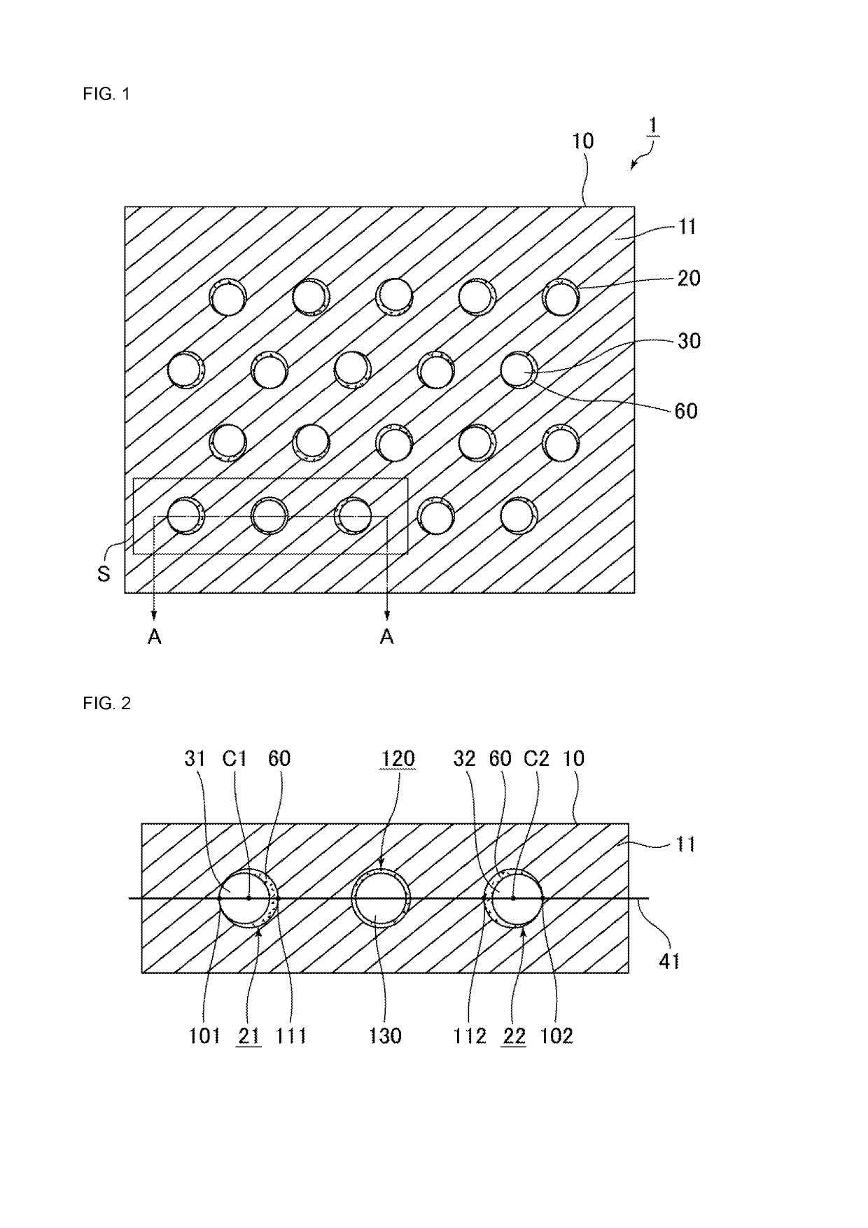

FIG. 1 is a top view of a through-conductor built-in substrate according to an aspect of the present disclosure when viewed from a first main surface side of a base plate. FIG. 1 does not show a metal layer on the first main surface side of the base plate so as to make it possible to see through holes and through conductors.

FIG. 2 is a top view of a region S portion of the through-conductor built-in substrate shown in FIG. 1.

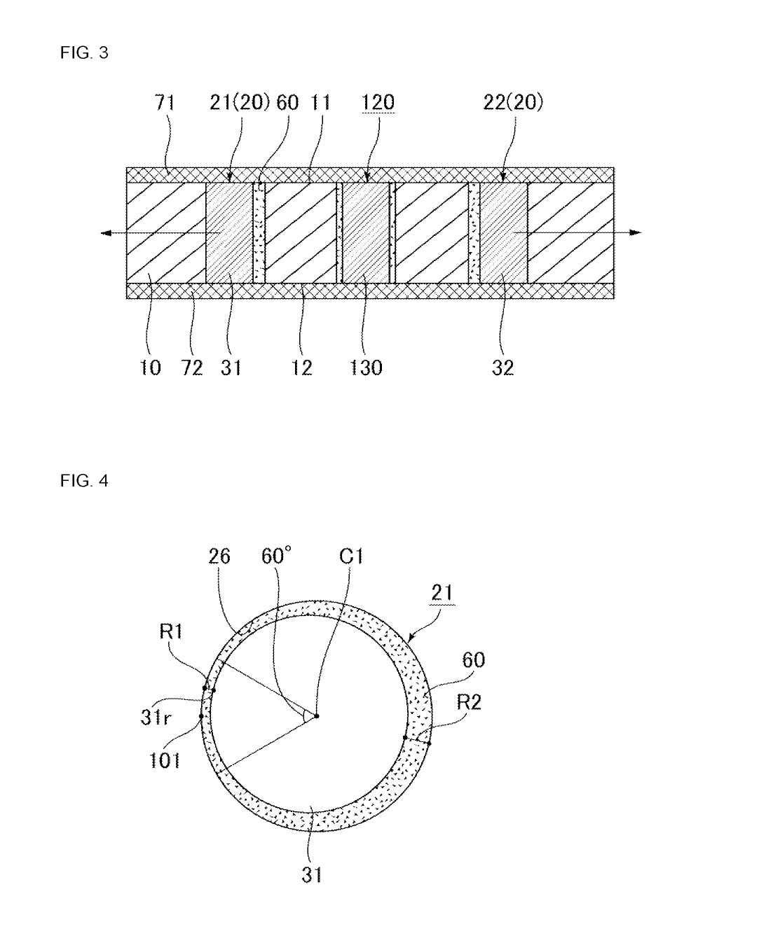

FIG. 3 is a cross-sectional view taken along line A-A of the through-conductor built-in substrate shown in FIG. 1, and shows a structure including the metal layer on the first main surface side and a metal layer on a second main surface side of the base plate.

In a through-conductor built-in substrate 1 shown in FIG. 1, a first main surface 11 of a base plate 10 is shown.

The base plate 10 includes a plurality of through holes 20, and through conductors 30 are inserted in the through holes 20. The through-conductor built-in substrate in its entirety includes the plurality of through holes and the plurality of through conductors. Since one through conductor is inserted in one through hole, the through-conductor built-in substrate includes the plurality of through holes in each of which one through conductor is inserted.

FIG. 1 shows resins 60 that fill spaces between the through conductors 30 and the respective through holes 20.

FIG. 3 shows a cross section of the base plate 10. The base plate 10 includes the first main surface 11 and a second main surface 12 that is opposite to the first main surface 11, and includes the plurality of through holes 20 that extend along the second main surface 12 from the first main surface 11.

The base plate is preferably made of a material having high rigidity. The material preferably has a thermal expansion coefficient that is less than the thermal expansion coefficient of each metal layer and is harder than the resins that fill the respective through holes.

The material is preferably a material whose Young's modulus is greater than or equal to 10 GPa and less than or equal to 50 GPa as an index of the rigidity.

As the material of the base plate, the base plate is preferably a base plate that includes glass. When the base plate is a base plate that includes glass, the rigidity of the base plate is high, the thermal expansion coefficient of the base plate is less than the thermal expansion coefficient of each metal layer, and the base plate is harder than the resins that fill the respective through holes. An example of the base plate that includes glass is a composite base plate including resin and glass. A specific example of the glass that makes up the base plate that includes glass is E glass, and specific examples of the resins include epoxy resin. Examples of the composite base plate that includes resin and glass include a glass epoxy base plate.

The thickness of the base plate is preferably greater than or equal to 0.3 mm and less than or equal to 5.0 mm.

The thermal expansion coefficient of the base plate is preferably greater than or equal to 4 × 10⁻⁶/K and less than or equal to 14 × 10⁻⁶/K.

The base plate includes the plurality of through holes, and the through conductors are inserted in the respective through holes.

The shape of each through hole in top view is preferably circular, and the diameter of each through hole is preferably greater than or equal to 0.3 mm and less than or equal to 5 mm.

The length (the thickness) of each through hole is the same as the thickness of the base plate.

Each through conductor is made of a material that is a conductor of electricity or a conductor of heat. Each through conductor is preferably made of a metal material. The metal material is ordinarily a conductor of electricity and a conductor of heat. Each metal conductor is preferably copper. Examples of materials of the through conductors other than metal include ceramic materials and carbon materials, and many of them can be used as conductors of heat and some of them can be used as conductors of electricity. Examples include silicon carbide, aluminum nitride, alumina, and graphite.

Each through conductor is preferably made of a material whose electrical resistivity is greater than or equal to 0.017 μΩ·m and less than or equal to 0.022 μΩ·m. The material preferably has a thermal resistivity that is greater than or equal to 300 W/m·K and less than or equal to 400 W/m·K. The thermal expansion coefficient of each through conductor is preferably greater than or equal to 17 × 10⁻⁶/K and less than or equal to 70 × 10⁻⁶/K. The Young's modulus of each through conductor is preferably greater than or equal to 50 GPa and less than or equal to 300 GPa.

The shape of each through conductor is preferably a circular columnar shape (the shape in top view is a circular shape), and when the shape of each through conductor is a circular columnar shape, the diameter of a bottom surface is preferably greater than or equal to 0.2 mm and less than or equal to 4.9 mm. Regardless of the shape in top view of each through conductor and each through hole, the area ratio of the area in top view of each through conductor to the area in top view of each through hole is preferably less than or equal to 96%.

The length of each through conductor (the length along a thickness direction of each through hole) may be the same as the length of each through hole or may be less than the length of each through hole.

Resins preferably fill spaces between the through conductors and the through holes in which the through conductors are inserted.

Specific examples of the resins preferably include epoxy resin, silicon resin, acrylic resin, and polyimide resin. The resins are ordinarily materials that are softer than the through conductors and the base plate.

In the through-conductor built-in substrate of the present disclosure, the positions of the through conductors in the through holes are defined by focusing upon particular through holes (two or three through holes) among the through holes in which the through conductors are inserted.

First, an aspect of the present disclosure that focuses upon two through holes is described.

As shown in FIG. 1, in top view, through holes that satisfy relationships determined in the present disclosure are selected and focused upon. In FIG. 1, the through holes that are included in a region shown as a region S are focused upon.

The relationships below are established between two through holes that are focused upon.

That is, when a straight line that passes through the center of a first through hole and the center of a second through hole is a first reference line, a first through conductor contacts or is near, of intersections of an inner peripheral wall of the first through hole and the first reference line, a first intersection, which is an intersection on a far side from a second through hole, and a second through conductor contacts or is near, of intersections of an inner peripheral wall of the second through hole and the first reference line, a second intersection, which is an intersection on a far side from the first through hole.

Another through hole that is not focused upon may be provided between the two through holes that are focused upon, or another through hole that is not focused upon need not be provided between the two through holes that are focused upon.

The points above that the two through holes that are focused upon satisfy are described with reference to FIG. 2.

FIG. 2 shows the through holes and the through conductors that are included in the region S.

In FIG. 2, the through hole and the through conductor shown on the left side are a first through hole 21 and a first through conductor 31, and the through hole and the through conductor that are shown on the right side are a second through hole 22 and a second through conductor 32. These are the two through holes and the two through conductors that are focused upon in the region S.

The through hole and the through conductor shown in the center are a through hole 120 that is not focused upon and a through conductor 130 that is not focused upon.

A straight line that passes through a center C1 of the first through hole 21 and a center C2 of the second through hole 22 is a first reference line 41.

There are two intersections of an inner peripheral wall of the first through hole 21 and the first reference line 41, and the intersection on a far side from the second through hole 22 is a first intersection (reference numeral 101). The intersection on a near side from the second through hole 22 is an eleventh intersection (reference numeral 111).

Similarly, there are two intersections of an inner peripheral wall of the second through hole 22 and the first reference line 41, and the intersection on a far side from the first through hole 21 is a second intersection (reference numeral 102). The intersection on a near side from the first through hole 21 is a twelfth intersection (reference numeral 112).

The first through conductor 31 is inserted in the first through hole 21, and is positioned in the first through hole 21 on the far side from the second through hole 22. This is expressed as follows: the first through conductor 31 contacts or is near the first intersection 101. The first through conductor 31 is separated from the eleventh intersection 111, which is the intersection on the near side from the second through hole 22.

FIG. 2 shows a state in which a left end of the first through conductor 31 contacts the first intersection 101.

The second through conductor 32 is inserted in the second through hole 22, and is positioned in the second through hole 22 on the far side from the first through hole 21. This is expressed as follows: the second through conductor 32 contacts or is near the second intersection 102. The second through conductor 32 is separated from the twelfth intersection 112, which is the intersection on the near side from the first through hole 21.

FIG. 2 shows a state in which a right end of the second through conductor 32 contacts the second intersection 102.

Regarding "the through conductor contacts or is near the intersection" in the present description, when the through conductor is the first through conductor, the intersection that the through conductor contacts or is near is the first intersection, and when the through conductor is the second through conductor, the intersection that the through conductor contacts or is near is the second intersection.

When the through conductors contact the respective intersections, the forms are as shown in FIG. 2, and it is visually determined whether the through conductors are in positional relationships that allow them to contact the intersections in top view.

When the through conductors are near the intersections, the through conductors exist near the intersections without contacting the intersections. The positional relationships can also be visually determined in top view.

A case in which a through conductor is near an intersection is described with reference to FIG. 4.

FIG. 4 is an explanatory view illustrating a positional relationship when a through conductor and an intersection are near each other, and shows the relationship between the first through conductor 31, the first through hole 21, and the first intersection 101.

First, the location where the distance from a side surface (an outer periphery) of the first through conductor 31 to an inner peripheral wall 26 of the first through hole 21 becomes the shortest is focused upon, and this distance, that is, the shortest distance (indicated by a double-headed arrow R1 in FIG. 4) between the first through conductor 31 and the inner peripheral wall 26 of the first through hole 21 is measured. A point on the side surface of the first through conductor 31 is a nearest contact point 31r.

A fan shape is drawn so as to include an arc extending along the inner peripheral wall of the first through hole 21 from the first intersection 101 and at an angle of 30 degrees on each of two sides of a radius (a total of 60 degrees) connecting the center C1 of the first through hole 21 and the first intersection and being a center. If the nearest contact point 31r is in the above-described fan shape, the first through conductor 31 is positioned in the first through hole 21 on the far side from the second through hole 22.

In order to determine that the first through conductor 31 and the first intersection 101 are near each other, the shortest distance R1 (indicated by the double-headed arrow R1 in FIG. 4) between the first through conductor 31 and the inner peripheral wall 26 of the first through hole 21 needs to be small to some degree, and the aforementioned shortest distance R1 is preferably less than or equal to 20 μm.

As an index showing that the shortest distance between the first through conductor 31 and the inner peripheral wall 26 of the first through hole 21 is small to some degree, when a longest distance between the first through conductor 31 and the inner peripheral wall 26 of the first through hole 21 is R2 (indicated by a double-headed arrow R2 in FIG. 4), proximity can be expressed by [(R2 – R1)/(R1 + R2)] × 100(%), and the value of the proximity is preferably greater than or equal to 50%. The proximity is preferably greater than or equal to 70% and is even more preferably greater than or equal to 90%.

The relationships between the second through hole and the second through conductor are also the same.

FIG. 3 is a cross-sectional view taken along line A-A of the through-conductor built-in substrate shown in FIG. 1, and shows a structure including the metal layer on the first main surface side and the metal layer on the second main surface side of the base plate.

The first main surface 11 of the base plate 10 is provided with a metal layer 71 that extends in a surface direction that is the same as the surface direction of the first main surface 11, and the second main surface 12 is provided with a metal layer 72 that extends in a surface direction that is the same as the surface direction of the second main surface 12.

The first through conductor 31 and the second through conductor 32 are each connected to the metal layer 71 and the metal layer 72.

It should be noted that the through-conductor built-in substrate includes at least the metal layer (the metal layer 71) that extends in the surface direction that is the same as the surface direction of the first main surface, and need not include the metal layer on the second main surface side of the base plate.

Each metal layer is preferably a metal foil or a metal plating layer, and is preferably a copper foil or a copper plating layer. The thermal expansion coefficient of each metal layer is ordinarily higher than the thermal expansion coefficient of the base plate.

FIG. 3 shows a state in which the first through conductor 31 is situated toward the left side of the first through hole 21 and contacts the base plate 10 (contacts the inner peripheral wall 26 of the first through hole 21). In addition, FIG. 3 shows a state in which the second through conductor 32 is situated toward the right side of the second through hole 22 and contacts the base plate 10 (contacts an inner peripheral wall 26 of the second through hole 22).

The first through conductor 31 and the second through conductor 32 are each connected to the metal layer 71.

When the through-conductor built-in substrate 1 is heated and the metal layer 71 expands in a planar direction with respect to the base plate 10, since the thermal expansion coefficient of the metal layer 71 is larger than the thermal expansion coefficient of the base plate 10, stress is applied to the first through conductor 31 and the second through conductor 32 to move them in the planar direction of the base plate 10.

This stress is applied outward, and is applied leftward in the figure to the first through conductor 31, and is applied rightward in the figure to the second through conductor 32. FIG. 3 shows the directions of the stress by a leftward arrow from the first through conductor 31 and a rightward arrow from the second through conductor 32.

The left side of the first through conductor 31 contacts the base plate 10. Since the base plate 10 is made of a material having high rigidity, the first through conductor 31 cannot deform the base plate 10 and move. Similarly, the right side of the second through conductor 32 contacts the base plate 10. Since the base plate 10 is made of a material having high rigidity, the second through conductor 32 cannot deform the base plate 10 and move.

That is, even if the through-conductor built-in substrate is heated and a stress is applied to the first through conductor and the second through conductor to move them in the planar direction of the base plate, the first through conductor and the second through conductor are prevented from moving in the planar direction of the base plate.

Therefore, the above-described structure makes it possible to provide a through-conductor built-in substrate in which movement, caused by thermal stress, of the through conductors inserted in the through holes is prevented.

It should be noted that the existence of a through conductor 130 shown in the center of FIG. 3 and inserted in a through hole 120 is not related to the realization of the above-described effects.

In the through-conductor built-in substrate of the present disclosure, 30 or more through conductors are connected to one metal layer, and 10% or more of the through conductors that are connected to the metal layer are preferably through conductors whose centers are displaced from the centers of the through holes in which the through conductors are inserted.

The top view of FIG. 1 shows twenty through holes 20 and twenty through conductors 30, and the through conductors 30 are connected to the metal layer (not shown) (the metal layer 71 shown in FIG. 3). Of the twenty through conductors 30 shown in FIG. 1, those other than the through conductor shown in the center of the region S are those whose centers are displaced from the centers of the through holes in which the through conductors are inserted.

"The centers of the through conductors are displaced from the centers of the through holes in which the through conductors are inserted" here means that, regardless of toward which direction the through conductors are positioned in the through holes, the positions of the centers are displaced from each other.

With regard to a criterion for determining whether the positions of the centers are displaced from each other, when a circle having a diameter that is 10% of the diameter of a through hole is drawn with the center of the through hole being the center, and when the center of the through conductor corresponding thereto is not positioned within the circle, it is determined that the center of the through hole and the center of the through conductor are displaced from each other.

Although the aspect that focuses upon, of the through holes in which the through conductors are inserted, two particular through holes has been described up to this point, an aspect that focuses upon three particular through holes is described below.

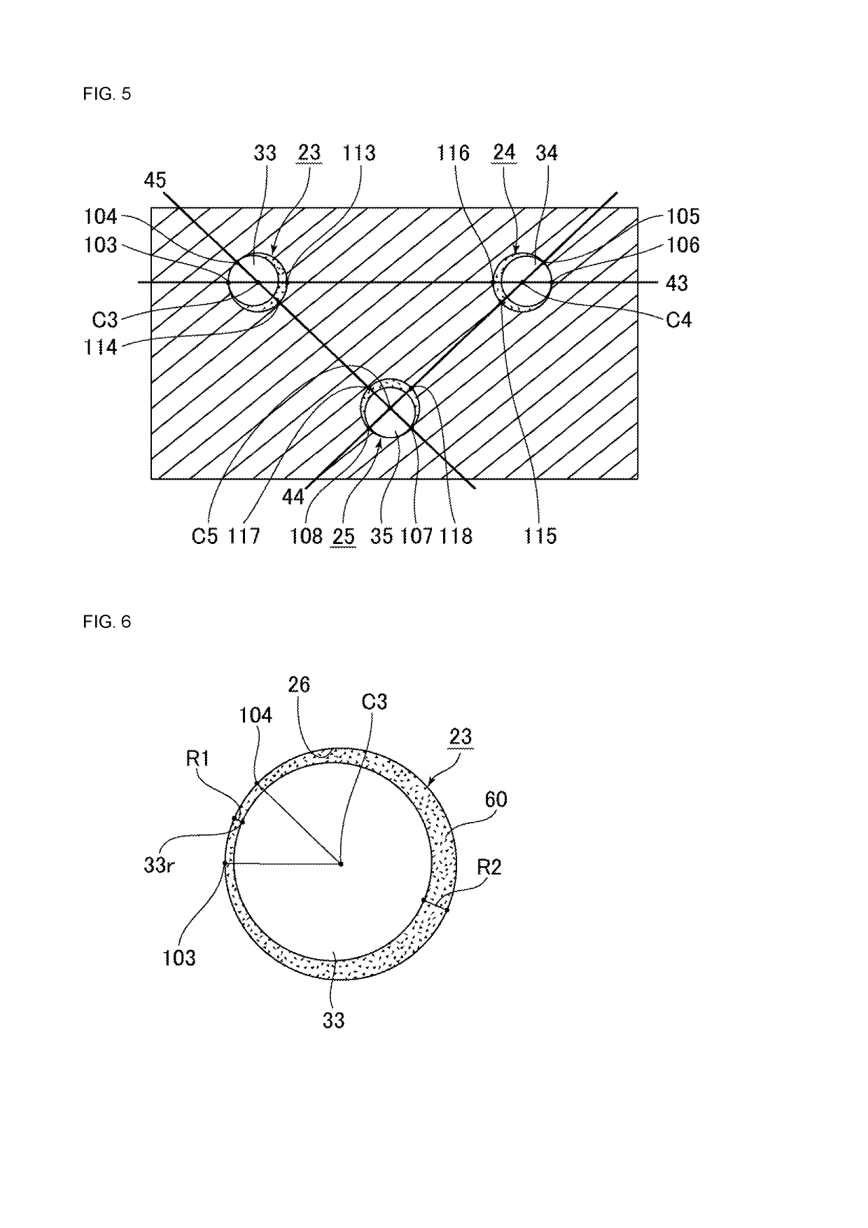

FIG. 5 is a top view showing three through holes and three through conductors that are focused upon.

In FIG. 5, the through hole and the through conductor shown on the upper left are a third through hole 23 and a third through conductor 33, the through hole and the through conductor that are shown on the upper right are a fourth through hole 24 and a fourth through conductor 34, and the through hole and the through conductor that are shown at the lower center are a fifth through hole 25 and a fifth through conductor 35. These are the three through holes and the three through conductors that are focused upon.

A straight line that passes through a center C3 of the third through hole 23 and a center C4 of the fourth through hole 24 is a third reference line 43.

A straight line that passes through a center C4 of the fourth through hole 24 and a center C5 of the fifth through hole 25 is a fourth reference line 44.

A straight line that passes through a center C5 of the fifth through hole 25 and a center C3 of the third through hole 23 is a fifth reference line 45.

There are two intersections of an inner peripheral wall of the third through hole 23 and the third reference line 43, and the intersection on a far side from the fourth through hole 24 is a third intersection (reference numeral 103). The intersection on a near side from the fourth through hole 24 is a thirteenth intersection (reference numeral 113).

There are two intersections of the inner peripheral wall of the third through hole 23 and the fifth reference line 45, and the intersection on a far side from the fifth through hole 25 is a fourth intersection (reference numeral 104). The intersection on a near side from the fifth through hole 25 is a fourteenth intersection (reference numeral 114).

There are two intersections of an inner peripheral wall of the fourth through hole 24 and the fourth reference line 44, and the intersection on a far side from the fifth through hole 25 is a fifth intersection (reference numeral 105). The intersection on a near side from the fifth through hole 25 is a fifteenth intersection (reference numeral 115).

There are two intersections of the inner peripheral wall of the fourth through hole 24 and the third reference line 43, and the intersection on a far side from the third through hole 23 is a sixth intersection (reference numeral 106). The intersection on a near side from the third through hole 23 is a sixteenth intersection (reference numeral 116).

There are two intersections of an inner peripheral wall of the fifth through hole 25 and the fifth reference line 45, and the intersection on a far side from the third through hole 23 is a seventh intersection (reference numeral 107). The intersection on a near side from the third through hole 23 is a seventeenth intersection (reference numeral 117).

There are two intersections of the inner peripheral wall of the fifth through hole 25 and the fourth reference line 44, and the intersection on a far side from the fourth through hole 24 is an eighth intersection (reference numeral 108). The intersection on a near side from the fourth through hole 24 is an eighteenth intersection (reference numeral 118).

The third through conductor 33 is inserted in the third through hole 23, and is positioned in the third through hole 23 on the far side from each of the fourth through hole 24 and the fifth through hole 25. This is expressed as follows: the third through conductor 33 contacts or is near a portion between the third intersection 103 and the fourth intersection 104. The third through conductor 33 is separated from the thirteenth intersection 113, which is the intersection on the near side from the fourth through hole 24, and is separated from the fourteenth intersection 114, which is the intersection on the near side from the fifth through hole 25.

FIG. 5 shows a state in which an upper left end of the third through conductor 33 contacts the inner peripheral wall of the third through hole 23 between the third intersection 103 and the fourth intersection 104.

The fourth through conductor 34 is inserted in the fourth through hole 24, and is positioned in the fourth through hole 24 on the far side from each of the fifth through hole 25 and the third through hole 23. This is expressed as follows: the fourth through conductor 34 contacts or is near a portion between the fifth intersection 105 and the sixth intersection 106. The fourth through conductor 34 is separated from the fifteenth intersection 115, which is the intersection on the near side from the fifth through hole 25, and is separated from the sixteenth intersection 116, which is the intersection on the near side from the third through hole 23.

FIG. 5 shows a state in which an upper right end of the fourth through conductor 34 contacts the inner peripheral wall of the fourth through hole 24 between the fifth intersection 105 and the sixth intersection 106.

The fifth through conductor 35 is inserted in the fifth through hole 25, and is positioned in the fifth through hole 25 on the far side from each of the third through hole 23 and the fourth through hole 24. This is expressed as follows: the fifth through conductor 35 contacts or is near a portion between the seventh intersection 107 and the eighth intersection 108. The fifth through conductor 35 is separated from the seventeenth intersection 117, which is the intersection on the near side from the third through hole 23, and is separated from the eighteenth intersection 118, which is the intersection on the near side from the fourth through hole 24.

FIG. 5 shows a state in which a lower end of the fifth through conductor 35 contacts the inner peripheral wall of the fifth through hole 25 between the seventh intersection 107 and the eighth intersection 108.

With regard to "the through conductor contacts or is near a portion between the intersection and the intersection" in the present description, "a portion between the intersection and the intersection" refers to a portion of the inner peripheral wall of the through hole between the intersection and the intersection, the portion being where the intersections are connected by the shortest distance along the inner peripheral wall. When the through conductor contacts this portion, this indicates that "the through conductor contacts the portion between the intersection and the intersection", and it is visually determined whether the through conductor is in a positional relationship that allows it to contact the portion between the intersections in top view.

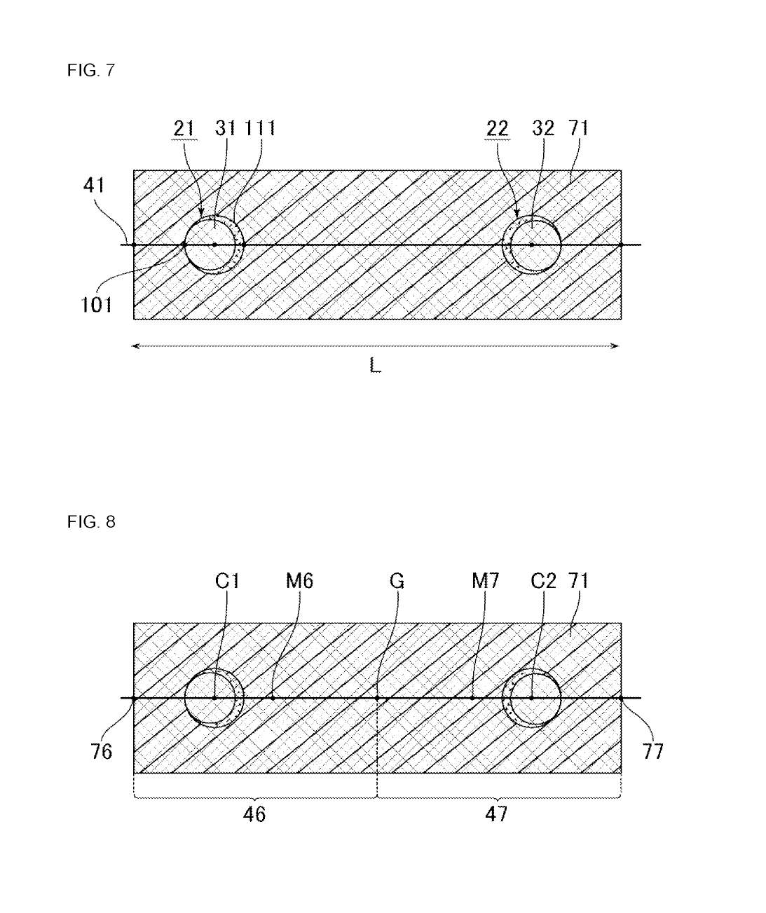

A case in which a through conductor is near a portion between an intersection and an intersection is described with reference to FIG. 6.

FIG. 6 is an explanatory view illustrating a positional relationship when a through conductor is near a portion between an intersection and an intersection, and shows the relationship between the third through conductor 33, the third through hole 23, the third intersection 103, and the fourth intersection 104.

First, a location where the distance between a side surface (an outer periphery) of the third through conductor 33 and the inner peripheral wall of the third through hole 23 becomes the shortest is focused upon, and this distance, that is, the shortest distance (indicated by a double-headed arrow R1 in FIG. 6) between the third through conductor 33 and the inner peripheral wall 26 of the third through hole 23 is measured. A point on the side surface of the third through conductor 33 is a nearest contact point 33r.

With the center C3 of the third through hole 23 being the center, a fan shape in which the third intersection 103 and the fourth intersection 104 are two ends of an arc is drawn. If the nearest contact point 33r is in the above-described fan shape, the third through conductor 33 can be said to be positioned in the third through hole 23 on the far sides from both the fourth through hole 24 and the fifth through hole 25.

In order to determine that the third through conductor 33 is near the portion between the third intersection 103 and the fourth intersection 104, the shortest distance (indicated by the double-headed arrow R1 in FIG. 6) between the third through conductor 33 and the inner peripheral wall 26 of the third through hole 23 needs to be small to some degree, and the aforementioned shortest distance R1 is preferably less than or equal to 20 μm.

As an index showing that the shortest distance between the third through conductor 33 and the inner peripheral wall 26 of the third through hole 23 is small to some degree, when a longest distance between the third through conductor 33 and the inner peripheral wall 26 of the third through hole 23 is R2 (indicated by a double-headed arrow R2 in FIG. 6), proximity can be expressed by [(R2 – R1)/(R1 + R2)] × 100(%), and the value of the proximity is preferably greater than or equal to 50%. The proximity is more preferably greater than or equal to 70%, and is even more preferably greater than or equal to 90%.

The relationship between the fourth through hole and the fourth through conductor and the relationship between the fifth through hole and the fifth through conductor are also the same.

Similarly to the above-described aspects that focuses upon two particular through holes, even in the aspect that focuses upon three particular through holes, when an outward stress is applied to each through conductor inserted in the through hole corresponding thereto, each through conductor is prevented from deforming the base plate and moving in the planar direction of the base plate. Therefore, it is possible to provide a through-conductor built-in substrate in which movement, caused by thermal stress, of the through conductors inserted in the through holes is prevented.

Further, an example of a positional relationship of through holes and through conductors with respect to a metal layer is described.

First, an aspect of the present disclosure that focuses upon, of through holes in which through conductors are inserted, two particular through holes is described.

In the through-conductor built-in substrate of the present disclosure, the metal layer may include a longitudinal direction, and the first reference line may extend along the longitudinal direction.

FIG. 7 is a top view illustrating a positional relationship between two through holes and two through conductors that are focused upon, and the metal layer.

In FIG. 7, in order to show the positional relationship between the through holes, the through conductors, and the metal layer, the metal layer is made transparent and the through holes and the through conductors are shown together with the metal layer.

FIG. 7 shows a metal layer 71, which is a metal layer on the first main surface side of the base plate, a first through hole 21 and a first through conductor 31 that is inserted in the first through hole 21, and a second through hole 22 and a second through conductor 32 that is inserted in the second through hole 22. A first reference line 41 is also shown.

The metal layer 71 has a rectangular shape in top view and includes a longitudinal direction. The longitudinal direction is a direction along a long side of the rectangular shape, and the longitudinal direction is indicated by a double-headed arrow L in FIG. 7.

In the aspect shown in FIG. 7, the first reference line 41 extends along the longitudinal direction L of the metal layer 71. In the present description, "the reference line extends along the longitudinal direction" indicates that the reference line is parallel to the longitudinal direction or is slightly displaced from the parallel direction. If the angle (acute angle) between the reference line and the longitudinal direction is less than or equal to 5 degrees, it can be said that the reference line extends along the longitudinal direction.

The longitudinal direction of the metal layer is a direction in which there is an increase in a force that is intended to move the through conductors that are inserted in the two through holes that are focused upon when a thermal stress is applied to the through conductors.

When the first through hole 21 is focused upon, if the first reference line 41 extends along the longitudinal direction L of the metal layer 71, the first through hole 21, the first through conductor 31, a first intersection 101, and an eleventh intersection 111 can be said to exist along the longitudinal direction L of the metal layer 71. That the first through conductor 31 is intended to move along the longitudinal direction of the metal layer 71 with respect to the thermal stress can be said to mean that the first through conductor is intended to move toward the first intersection 101 along the first reference line 41. In the through-conductor built-in substrate of the present disclosure, since the first through conductor 31 contacts or is near the first intersection 101, movement of the first through conductor 31 in this direction is suppressed.

Therefore, as a result of the metal layer including the longitudinal direction and the first reference line extending in the longitudinal direction, the direction in which the through conductors are intended to move due to the thermal stress that is applied to the through-conductor built-in substrate and the direction in which movement of the through conductors due to the thermal stress is effectively prevented are the same. Thus, movement, caused by the thermal stress, of the through conductors inserted in the through holes can be effectively prevented.

The two through holes and the two through conductors that are focused upon are preferably positioned near two end portions of the metal layer along the longitudinal direction. This positional relationship more effectively realizes the effects provided by the structure of the through-conductor built-in substrate of the present disclosure.

That is, when, with the center of gravity of the metal layer being a starting point, a straight line that passes through the center of the first through hole and reaches an end portion of the metal layer is a sixth reference line, the center of the first through hole is preferably positioned in a region that is nearer the end portion of the metal layer than the center of gravity of the metal layer on the sixth reference line; and when, with the center of gravity of the metal layer being a starting point, a straight line that passes through the center of the second through hole and reaches an end portion of the metal layer is a seventh reference line, the center of the second through hole is preferably positioned in a region that is nearer the end portion of the metal layer than the center of gravity of the metal layer on the seventh reference line.

It should be noted that, in the present description, the center of gravity of the metal layer is defined as a center of gravity of a flat plate without outer edges of the metal layer (a smallest rectangular shape that is defined to include all wires that make up the metal layer).

FIG. 8 is a top view illustrating a positional relationship between two through holes and two through conductors that are focused upon, and a metal layer. Although FIG. 8 shows the same positional relationship as in FIG. 7, the illustrated reference line differs from that of FIG. 7.

FIG. 8 shows a sixth reference line 46, which is a straight line that, with a center of gravity G of a metal layer 71 being a starting point, passes through a center C1 of a first through hole 21 and reaches an end portion 76 of the metal layer. FIG. 8 also shows a seventh reference line 47, which is a straight line that, with the center of gravity G of the metal layer 71 being a starting point, passes through a center C2 of a second through hole 22 and reaches an end portion 77 of the metal layer.

The center C1 of the first through hole 21 is positioned in a region on a side that is nearer the end portion 76 of the metal layer 71 than the center of gravity G of the metal layer 71 on the sixth reference line 46. This indicates that, when, with a middle point M6 of the sixth reference line 46 being a boundary, a region on the side of the center of gravity G and a region on the side of the end portion 76 are separately provided, the center C1 of the first through hole 21 is positioned in the region on the side of the end portion 76.

Similarly, the center C2 of the second through hole 22 is positioned in a region on a side that is nearer the end portion 77 of the metal layer 71 than the center of gravity G of the metal layer 71 on the seventh reference line 47. This indicates that, when, with a middle point M7 of the seventh reference line 47 being a boundary, a region on a side of the center of gravity G and a region on a side of the end portion 77 are separately provided, the center C2 of the second through hole 22 is positioned in the region on the side of the end portion 77.

When the two through holes and the two through conductors that are focused upon are positioned near a corresponding one of the two end portions along the longitudinal direction of the metal layer, the effects provided by the structure of the through-conductor built-in substrate of the present disclosure are more effectively realized. Therefore, when, as defined above, the first through hole 21 is positioned in the region on the side nearer the end portion 76 and the second through hole 22 is positioned in the region on the side nearer the end portion 77, the effects of the present disclosure are more effectively realized.

Next, as an example of a positional relationship of through holes and through conductors with respect to a metal layer, an aspect that focuses upon, of through holes in which through conductors are inserted, three particular through holes is described.

When three particular through holes are focused upon, the three through holes are preferably positioned near end portions of the metal layer. This positional relationship more effectively realizes the effects provided by the structure of the through-conductor built-in substrate of the present disclosure.

Specifically, when, with the center of gravity of the metal layer being a starting point, a straight line that passes through the center of a third through hole and reaches an end portion of the metal layer is an eighth reference line, the center of the third through hole is preferably positioned in a region on a side that is nearer the end portion of the metal layer than the center of gravity of the metal layer on the eighth reference line; when, with the center of gravity of the metal layer being a starting point, a straight line that passes through the center of a fourth through hole and reaches an end portion of the metal layer is a ninth reference line, the center of the fourth through hole is preferably positioned in a region on a side that is nearer the end portion of the metal layer than the center of gravity of the metal layer on the ninth reference line; and when, with the center of gravity of the metal layer being a starting point, a straight line that passes through the center of a fifth through hole and reaches an end portion of the metal layer is a tenth reference line, the center of the fifth through hole is preferably positioned in a region on a side that is nearer the end portion of the metal layer than the center of gravity of the metal layer on the tenth reference line.

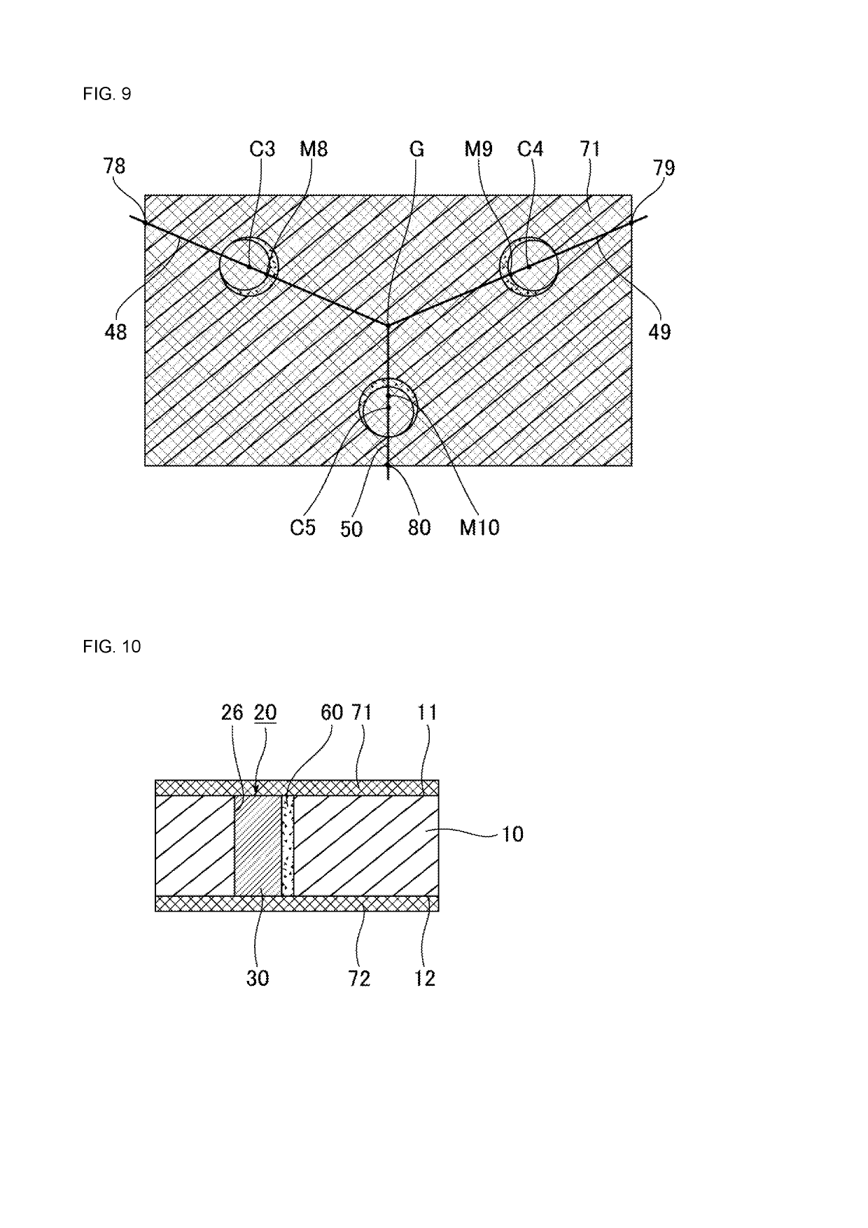

FIG. 9 is a top view illustrating a positional relationship between three through holes and three through conductors that are focused upon, and a metal layer.

FIG. 9 shows an eighth reference line 48, which is a straight line that, with a center of gravity G of a metal layer 71 being a starting point, passes through a center C3 of a third through hole 23 and reaches an end portion 78 of the metal layer. FIG. 9 also shows a ninth reference line 49, which is a straight line that passes through the center of gravity G of the metal layer 71 and a center C4 of a fourth through hole 24 and reaches an end portion 79 of the metal layer. FIG. 9 also shows a tenth reference line 50, which is a straight line that passes through the center of gravity G of the metal layer 71 and a center C5 of a fifth through hole 25 and reaches an end portion 80 of the metal layer.

The center C3 of the third through hole 23 is positioned in a region on a side that is nearer the end portion 78 of the metal layer 71 than the center of gravity G of the metal layer 71 on the eighth reference line 48. This indicates that, when, with a middle point M8 of the eighth reference line 48 being a boundary, a region on a side of the center of gravity G and a region on a side of the end portion 78 are separately provided, the center C3 of the third through hole 23 is positioned in the region on the side of the end portion 78.

Similarly, the center C4 of the fourth through hole 24 is positioned in a region on a side that is nearer the end portion 79 of the metal layer 71 than the center of gravity G of the metal layer 71 on the ninth reference line 49. This indicates that, when, with a middle point M9 of the ninth reference line 49 being a boundary, a region on a side of the center of gravity G and a region on a side of the end portion 79 are separately provided, the center C4 of the fourth through hole 24 is positioned in the region on the side of the end portion 79.

Similarly, the center C5 of the fifth through hole 25 is positioned in a region on a side that is nearer the end portion 80 of the metal layer 71 than the center of gravity G of the metal layer 71 on the tenth reference line 50. This indicates that, when, with a middle point M10 of the tenth reference line 50 being a boundary, a region on a side of the center of gravity G and a region on a side of the end portion 80 are separately provided, the center C5 of the fifth through hole 25 is positioned in the region on the side of the end portion 80.

When the three through holes and the three through conductors that are focused upon are positioned near a corresponding one of the end portions of the metal layer, the effects provided by the structure of the through-conductor built-in substrate of the present disclosure are more effectively realized. Therefore, when, as defined above, the third through hole 23 is positioned in the region on the side nearer the end portion 78, the fourth through hole 24 is positioned in the region on the side nearer the end portion 79, and the fifth through hole 25 is positioned in the region on the side nearer the end portion 80, the effects of the present disclosure are more effectively realized.

Further, an example of a positional relationship of through holes and through conductors with respect to a metal layer is described.

In the through-conductor built-in substrate of the present disclosure, in a cross section in a thickness direction along a direction in which the first main surface and the second main surface of the base plate are connected, at least one of the through conductors may be in line-contact with the inner peripheral wall of the through hole in which the at least one of the through conductors is inserted.

FIG. 10 is a cross-sectional view schematically showing a form in which a through conductor is in line-contact with an inner peripheral wall of a through hole in which the through conductor is inserted.

The cross-sectional view of FIG. 10 is a cross-sectional view in a thickness direction along a direction in which the first main surface 11 and the second main surface 12 of the base plate 10 are connected.

A through conductor 30 is inserted in a through hole 20, and a side surface of the through conductor 30 contacts a line indicating an inner peripheral wall 26 of the through hole 20 such that the side surface coincides with the line. As a result, the side surface is in line contact with the inner peripheral wall.

Since the shapes in top view of the through hole 20 and the through conductor 30 are both circular and have different diameters, the through hole 20 and the through conductor 30 when they contact each other are in line-contact with each other instead of being in surface-contact with each other. When the through conductor 30 is in line contact with the inner peripheral wall 26 of the through hole 20, the effect of preventing movement, caused by thermal stress, of the through conductor 30 inserted in the through hole 20 is more effectively realized.

It should be noted that, of the plurality of through holes and the plurality of through conductors of the through-conductor built-in substrate, all of the through holes may be in line-contact with the inner peripheral walls of the respective through conductors, or some of the through holes may be in line-contact with the inner peripheral walls of the through conductors.

In the through-conductor built-in substrate of the present disclosure, in the cross section in the thickness direction along the direction in which the first main surface and the second main surface of the base plate are connected, the length of at least one of the through conductors along a thickness direction of the through conductor may be shorter than the length along a thickness direction of the through hole in which the at least one of the through conductors is inserted, and, at a location that is separated from an end portion of the through hole in the thickness direction thereof, the at least one of the through conductors may contact or may be near the inner peripheral wall of the through hole in which the at least one of the through conductors is inserted.

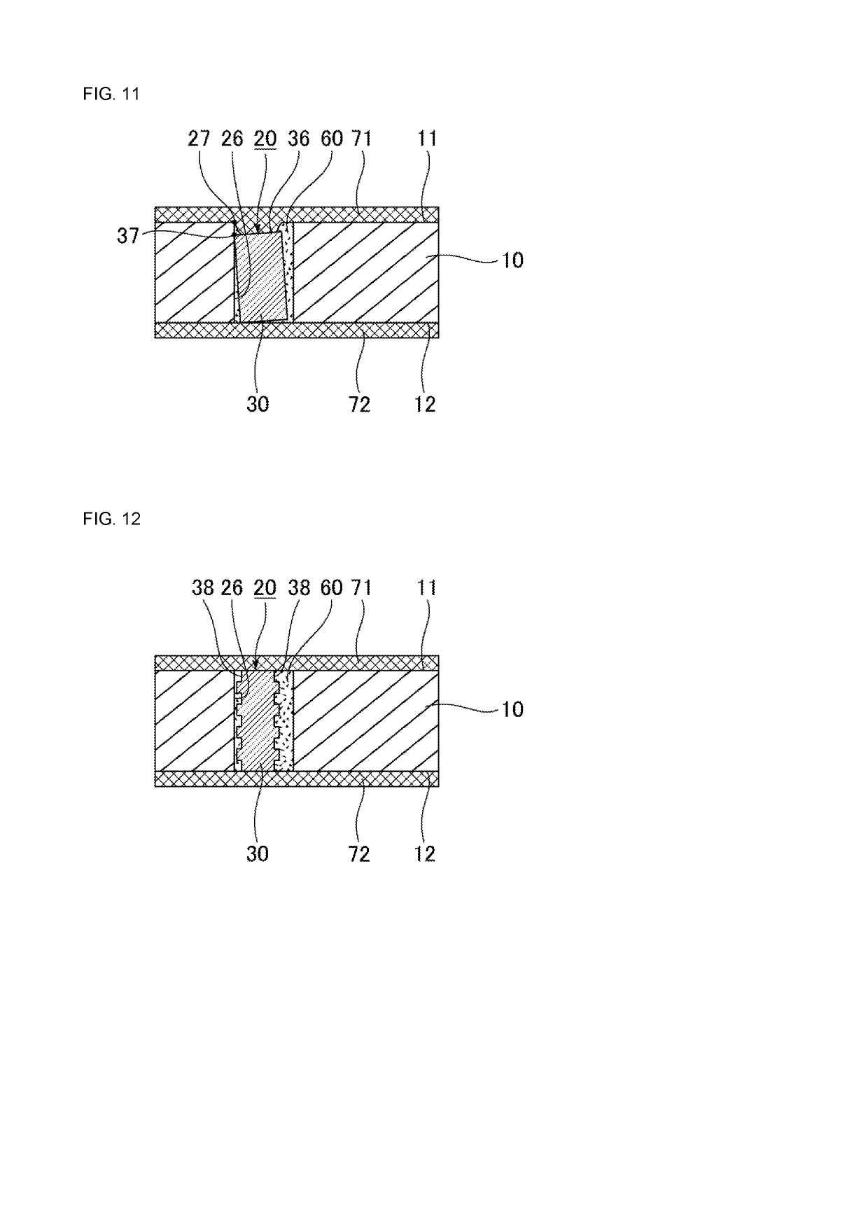

FIG. 11 is a cross-sectional view schematically showing a form in which the length of a through conductor is less than the length of a through hole.

The cross-sectional view of FIG. 11 is a cross-sectional view in a thickness direction along a direction in which the first main surface 11 and the second main surface 12 of the base plate 10 are connected.

A through conductor 30 is inserted in a through hole 20, and the length of the through hole 30 along a thickness direction is less than the length of the through hole 20 along the thickness direction thereof. Therefore, a metal layer 71 extends into the through hole 20 so as to contact an upper surface 36 of the through conductor 30.

At a contact point 37, which is a position that is separated from an end portion 27 of the through hole 20 in the thickness direction, the through conductor 30 contacts an inner peripheral surface 26 of the through hole 20. It can be said that the through conductor 30 is tilted in the through hole 20 instead of a side surface of the through conductor 30 being parallel to the inner peripheral surface of the through hole 20.

Since, at the contact point 37, the through conductor 30 contacts the inner peripheral wall 26, which is a surface of the base plate 10, of the through hole 20, even this form realizes the effect of preventing movement, caused by thermal stress, of the through conductor 30 inserted in the through hole 20.

At the location that is separated from the end portion of the through hole in the thickness direction thereof, the through conductor may contact or may be near the inner peripheral wall of the through hole in which the through conductor is inserted. The definition of the inner peripheral wall and the through conductor being near each other is as explained above; and with, in the cross section in the thickness direction, a point where the distance between the tilted through conductor and the inner peripheral wall of the through hole becomes the shortest being a nearest contact point, the shortest distance between the through conductor and the inner peripheral wall of the through hole is defined to determine whether the inner peripheral wall and the through conductor are near each other.

Note, of the plurality of through holes and the plurality of the through conductors of the through-conductor built-in substrate, all of the through conductors may have lengths along the thickness direction that are less than the lengths along the thickness direction of the through holes in which the through conductors are inserted, and, at a location that is separated from the end portion of the through hole in the thickness direction, each of these through conductors may contact or may be near the inner peripheral wall of the through hole in which the through conductor is inserted.

The lengths of some of the through conductors along the thickness direction may be less than the lengths along the thickness direction of the through holes in which the through conductors are inserted, and, at a location that is separated from the end portion of the through hole in the thickness direction, each of these through conductors may contact or may be near the inner peripheral wall of the through hole in which the through conductor is inserted.

Next, an example of a surface state of a through hole and a through conductor in a cross-sectional view in a thickness direction is described.

In the through-conductor built-in substrate of the present disclosure, a side surface of a through conductor may have an uneven portion. The uneven portion of the through conductor may have a size that is greater than or equal to 1 μm with a surface roughness of Ra.

FIG. 12 is a cross-sectional view schematically showing a form in which a side surface of a through conductor has an uneven portion.

FIG. 12 shows a form in which a side surface of a through conductor 30 has an uneven portion 38. When the side surface of the through conductor 30 has the uneven portion 38, an anchor effect occurs at a contact surface between the uneven portion and the resin 60 in the vicinity of the through conductor 30, and the through conductor 30 and the resin 60 are strongly joined, as a result of which a failure mode in which the through conductor 30 comes off the resin 60 is prevented.

The uneven portion 38 of the side surface of the through conductor 30 may be provided on the entire side surface of the through conductor 30 or on part of the side surface of the through conductor 30.

The size of the uneven portion 38 of the side surface of the through conductor 30 may be greater than or equal to 1 μm with the surface roughness of Ra. The size of the uneven portion 38 of the side surface of the through conductor 30 may be less than or equal to 10 μm with the surface roughness of Ra. The surface roughness can be measured by taking a photograph of a cross section including the side surface of the through conductor and by performing image analysis.

In the through-conductor built-in substrate of the present disclosure, an inner peripheral wall of a through hole may have an uneven portion. The size of the uneven portion of the inner peripheral wall of the through hole may be greater than or equal to 1 μm with a surface roughness of Ra.

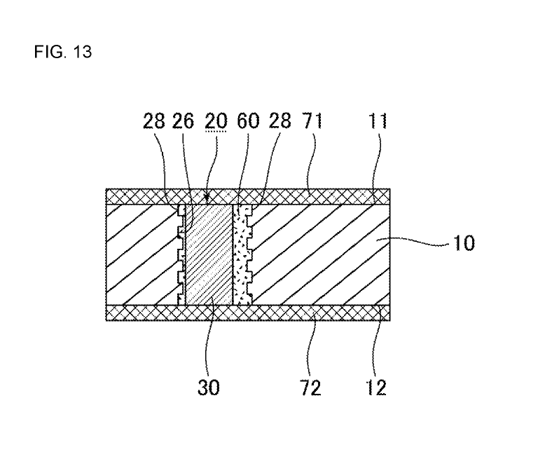

FIG. 13 is a cross-sectional view schematically showing a form in which an inner peripheral wall of a through hole has an uneven portion.

FIG. 13 shows a form in which an inner peripheral wall 26 of a through hole 20 has an uneven portion 28. When the inner peripheral wall 26 of the through hole 20 has the uneven portion 28, an anchor effect occurs at a contact surface between the uneven portion and the resin 60 in the through hole 20, and the inner peripheral wall 26 of the through hole 20 and the resin 60 are strongly joined, as a result of which a failure mode in which the resin 60 comes off the through hole 20 and the through conductor 30 comes off together with the resin 60 is prevented.

The uneven portion 28 of the inner peripheral wall 26 of the through hole 20 may be provided on the entire inner peripheral wall 26 of the through hole 20 or on part of the inner peripheral wall 26 of the through hole 20.

The size of the uneven portion 28 of the inner peripheral wall 26 of the through hole 20 may be greater than or equal to 1 μm with a surface roughness of Ra. The size of the uneven portion 28 of the inner peripheral wall 26 of the through hole 20 may be less than or equal to 50 μm with the surface roughness of Ra. The surface roughness can be measured by taking a photograph of a cross section including the inner peripheral wall of the through hole and by performing image analysis.

An uneven portion may be provided on a side surface of a through conductor and an uneven portion may be provided on an inner peripheral wall of a through hole. It is preferable that the side surface and the inner peripheral wall both have an uneven portion because the through conductor and the inner peripheral wall of the through hole are both more strongly joined to the resin. The uneven portions in this case may have the same size or difference sizes.

Examples of a method of providing a side surface of a through conductor or an inner peripheral wall of a through hole with an uneven portion include physical processing, such as cutting or sandblasting, and chemical processing, such as etching. However, the method is not limited to these examples.

Although a method of producing the through-conductor built-in substrate of the present disclosure is not particularly limited, the through-conductor built-in substrate of the present disclosure can be produced by preparing a base plate including a plurality of through holes, inserting through conductors into the through holes, embedding resins into spaces in the respective through holes, and providing a metal layer on a first main surface and a second main surface of the base plate by plating.

In this process, the position where a component mounting machine is mounted is displaced from the center of each through hole and each component is mounted (each through conductor is mounted), to make it possible to form the through-conductor built-in substrate of the present disclosure.

In general, the description of the aspects disclosed should be considered as being illustrative in all respects and not being restrictive. The scope of the present disclosure is shown by the claims rather than by the above description and is intended to include meanings equivalent to the claims and all changes in the scope. While preferred aspects of the invention have been described above, it is to be understood that variations and modifications will be apparent to those skilled in the art without departing from the scope and spirit of the invention

### REFERENCE SIGNS LIST

1 through-conductor built-in substrate

10 base plate

11 first main surface

12 second main surface

20 through hole

21 first through hole

22 second through hole

23 third through hole

24 fourth through hole

25 fifth through hole

26 inner peripheral wall of through hole

27 end portion of through hole in thickness direction

28 uneven portion of inner peripheral wall of through hole

30 through conductor

31 first through conductor

31r nearest contact point of first through conductor

32 second through conductor

33 third through conductor

33r nearest contact point of third through conductor

34 fourth through conductor

35 fifth through conductor

36 upper surface of through conductor

37 contact point of through conductor

38 uneven portion of side surface of through conductor

41 first reference line

43 third reference line

44 fourth reference line

45 fifth reference line

46 sixth reference line

47 seventh reference line

48 eighth reference line

49 ninth reference line

50 tenth reference line

60 resin

70 metal layer

71 metal layer on first main surface side of base plate

72 metal layer on second main surface side of base plate

76, 77, 78, 79, 80 end portion of metal layer

101 first intersection

102 second intersection

103 third intersection

104 fourth intersection

105 fifth intersection

106 sixth intersection

107 seventh intersection

108 eighth intersection

111 eleventh intersection

112 twelfth intersection

113 thirteenth intersection

114 fourteenth intersection

115 fifteenth intersection

116 sixteenth intersection

117 seventeenth intersection

118 eighteenth intersection

120 through hole that is not focused upon

130 through conductor that is not focused upon

C1 center of first through hole

C2 center of second through hole

C3 center of third through hole

C4 center of fourth through hole

C5 center of fifth through hole

G center of gravity of metal layer

R1 shortest distance between through conductor and inner peripheral wall of through hole

R2 longest distance between through conductor and inner peripheral wall of through hole

M6, M7, M8, M9, M10 middle point

1. A through-conductor built-in substrate comprising:
a base plate including a first main surface, a second main surface, and a plurality of through holes, the second main surface being opposite to the first main surface, the plurality of through holes extending along the second main surface from the first main surface;
through conductors in the plurality of through holes; and
a metal layer extending in a surface direction, the surface direction being a same as a surface direction of the first main surface, the metal layer connected to the through conductors,
wherein the plurality of through holes include a first through hole and a second through hole, which are different through holes,
wherein the through conductors include a first through conductor and a second through conductor, the first through conductor is inserted in the first through hole, the second through conductor is inserted in the second through hole,
wherein the first through conductor and the second through conductor are each connected to the metal layer, and
wherein, when a straight line that passes through a center of the first through hole and a center of the second through hole is a first reference line,
the first through conductor contacts or is near, of intersections of an inner peripheral wall of the first through hole and the first reference line, a first intersection, which is an intersection on a far side from the second through hole, and
the second through conductor contacts or is near, of intersections of an inner peripheral wall of the second through hole and the first reference line, a second intersection, which is an intersection on a far side from the first through hole.

2. The through-conductor built-in substrate according to claim 1, wherein the metal layer includes a longitudinal direction, and the first reference line extends along the longitudinal direction.

3. The through-conductor built-in substrate according to claim 1, wherein, when, with a center of gravity of the metal layer being a starting point, a straight line that passes through the center of the first through hole and reaches an end portion of the metal layer is a sixth reference line, the center of the first through hole is positioned in a region on a side that is nearer the end portion of the metal layer than the center of gravity of the metal layer on the sixth reference line.

4. The through-conductor built-in substrate according to claim 3, wherein, when, with the center of gravity of the metal layer being a starting point, a straight line that passes through the center of the second through hole and reaches an end portion of the metal layer is a seventh reference line, the center of the second through hole is positioned in a region on a side that is nearer the end portion of the metal layer than the center of gravity of the metal layer on the seventh reference line.

5. The through-conductor built-in substrate according to claim 4, wherein, when, with a center of gravity of the metal layer being a starting point, a straight line that passes through the center of a third through hole and reaches an end portion of the metal layer is an eighth reference line, the center of the third through hole is positioned in a region on a side that is nearer the end portion of the metal layer than the center of gravity of the metal layer on the eighth reference line.

6. The through-conductor built-in substrate according to claim 5, wherein, when, with the center of gravity of the metal layer being a starting point, a straight line that passes through the center of a fourth through hole and reaches an end portion of the metal layer is a ninth reference line, the center of the fourth through hole is positioned in a region on a side that is nearer the end portion of the metal layer than the center of gravity of the metal layer on the ninth reference line.

7. The through-conductor built-in substrate according to claim 6, wherein, when, with the center of gravity of the metal layer being a starting point, a straight line that passes through the center of a fifth through hole and reaches an end portion of the metal layer is a tenth reference line, the center of the fifth through hole is positioned in a region on a side that is nearer the end portion of the metal layer than the center of gravity of the metal layer on the tenth reference line.

8. The through-conductor built-in substrate according to claim 1, wherein, in a cross section in a thickness direction along a direction in which the first main surface and the second main surface of the base plate are connected.

9. The through-conductor built-in substrate according to claim 8, wherein at least one of the through conductors is in line-contact with an inner peripheral wall of the through hole in which the at least one of the through conductors is inserted.

10. The through-conductor built-in substrate according to claim 1, wherein, in a cross section in a thickness direction along a direction in which the first main surface and the second main surface of the base plate are connected, a length of at least one of the through conductors along a thickness direction of the through conductor is shorter than a length along a thickness direction of the through hole in which the at least one of the through conductors is inserted, and, at a location that is separated from an end portion of the through hole in the thickness direction thereof, the at least one of the through conductors contacts or is near an inner peripheral wall of the through hole in which the at least one of the through conductors is inserted.

11. The through-conductor built-in substrate according to claim 1, wherein the through conductors, which are 30 or more through conductors, are connected to the metal layer, which is one metal layer, and 10% or more of the through conductors that are connected to the metal layer are through conductors whose centers are displaced from centers of the through holes in which the through conductors are inserted.

12. The through-conductor built-in substrate according to claim 1, wherein resins fill spaces between the through conductors and the through holes in which the through conductors are inserted.

13. The through-conductor built-in substrate according to claim 12, wherein each of the resins is epoxy resin, silicon resin, acrylic resin, or polyimide resin.

14. The through-conductor built-in substrate according to claim 1, wherein a side surface of each of the through conductors has an uneven portion.

15. The through-conductor built-in substrate according to claim 14, wherein the uneven portion of each of the through conductors has a size that is greater than or equal to 1 μm with a surface roughness of Ra.

16. The through-conductor built-in substrate according to claim 1, wherein an inner peripheral wall of each of the through holes has an uneven portion.

17. The through-conductor built-in substrate according to claim 1, wherein each of the through conductors is made of a metal material.

18. The through-conductor built-in substrate according to claim 1, wherein the base plate is a glass base plate.

19. A through-conductor built-in substrate comprising:
a base plate having opposing first and second main surfaces and a plurality of through holes extending therebetween;
through conductors respectively inserted in the through holes; and
a metal layer extending in a surface direction of the first main surface and connected to the through conductors;
wherein the plurality of through holes include first and second through holes with corresponding first and second through conductors therein; and
wherein a straight line passing through centers of the first and second through holes intersects inner peripheral walls of the first and second through holes at respective locations on sides, and the first and second through conductors are positioned to contact or be positioned adjacent the respective locations so as to inhibit lateral displacement of the through conductors in a plane of the base plate under thermal stress transmitted via the metal layer.

20. A through-conductor built-in substrate comprising:
a base plate including a first main surface, a second main surface, and a plurality of through holes, the second main surface being opposite to the first main surface, the plurality of through holes extending along the second main surface from the first main surface;
through conductors in the through holes; and
a metal layer extending in a surface direction that is same as a surface direction of the first main surface, the metal layer being connected to the through conductors,
wherein the through holes include a third through hole, a fourth through hole, and a fifth through hole, which are different through holes,
wherein the through conductors include a third through conductor, a fourth through conductor, and a fifth through conductor, the third through conductor in the third through hole, the fourth through conductor in the fourth through hole, the fifth through conductor in the fifth through hole,
wherein the third through conductor, the fourth through conductor, and the fifth through conductor are each connected to the metal layer,
wherein, when a straight line that passes through a center of the third through hole and a center of the fourth through hole is a third reference line, a straight line that passes through the center of the fourth through hole and a center of the fifth through hole is a fourth reference line, and a straight line that passes through the center of the fifth through hole and the center of the third through hole is a fifth reference line,
the third through conductor contacts or is near a portion between, of intersections of an inner peripheral wall of the third through hole and the third reference line, a third intersection and, of intersections of the inner peripheral wall of the third through hole and the fifth reference line, a fourth intersection, the third intersection being an intersection on a far side from the fourth through hole, the fourth intersection being an intersection on a far side from the fifth through hole,
the fourth through conductor contacts or is near a portion between, of intersections of an inner peripheral wall of the fourth through hole and the fourth reference line, a fifth intersection and, of intersections of the inner peripheral wall of the fourth through hole and the third reference line, a sixth intersection, the fifth intersection being an intersection on a far side from the fifth through hole, the sixth intersection being an intersection on a far side from the third through hole, and
the fifth through conductor contacts or is near a portion between, of intersections of an inner peripheral wall of the fifth through hole and the fifth reference line, a seventh intersection and, of intersections of the inner peripheral wall of the fifth through hole and the fourth reference line, an eighth intersection, the seventh intersection being an intersection on a far side from the third through hole, the eighth intersection being an intersection on a far side from the fourth through hole.
